(19) United States
(12) Patent Application Publication
(10) Pub. No.: US 2025/0246228 A1
(43) Pub. Date: Jul. 31, 2025

(54) MEMORY DEVICE

(71) Applicant: TAIWAN SEMICONDUCTOR MANUFACTURING COMPANY, LTD., Hsinchu (TW)

(72) Inventors: Zheng-Jun LIN, Taichung City (TW); Chung-Cheng CHOU, Hsinchu City (TW); Pei-Ling TSENG, Hsinchu City (TW)

(73) Assignee: TAIWAN SEMICONDUCTOR MANUFACTURING COMPANY, LTD., Hsinchu (TW)

(21) Appl. No.: 18/422,185

(22) Filed: Jan. 25, 2024

(51) Int. Cl. G11C 11/408; G11C 11/4093; G11C 11/4096

(52) U.S. Cl. CPC G11C 11/4085; G11C 11/4093; G11C 11/4096

(57) ABSTRACT

A memory device is provided. The memory device includes multiple first memory arrays, a first write word line driver, and multiple first read word line drivers. Each of the first read word line drivers is coupled to one array in the first memory arrays. A selected one in the first read word line drivers generates a first word line voltage to a corresponding array in the first memory arrays in a first read operation. A first write word line driver is coupled to at least two drivers in the first read word line drivers, and generates a second word line voltage to the first memory arrays in a first write operation. The second word line voltage is greater than the first word line voltage.

### BACKGROUND

In resistive random access memory device, word line drivers generate word line signals to drive memory cells during read and write operations. Specifically, the word line driver provides read word line pulse having a read word line voltage and fast rising edge in the read operation. The word line driver further provides write word line pulse having a write word line voltage and lower rising edge in the write operation.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a memory device, in accordance with various embodiments of the present disclosure.

FIG. 2 illustrates schematic diagrams of a write word line driver and a read word line driver that correspond to FIG. 1, in accordance with other embodiments of the present disclosure.

FIG. 3 illustrates waveforms of the read word line signal and the write word line signal corresponding to FIGS. 1-2, in accordance with some embodiments of the present disclosure.

FIG. 4 is a schematic diagram of part of a memory array corresponding to FIG. 1, in accordance with some embodiments of the present disclosure.

FIG. 5 is a schematic diagram of a memory device, in accordance with various embodiments of the present disclosure.

FIG. 6 is a schematic diagram of a memory device, in accordance with various embodiments of the present disclosure.

FIG. 7 is a schematic diagram of a memory device, in accordance with various embodiments of the present disclosure.

FIG. 8 is a schematic diagram of a memory device, in accordance with various embodiments of the present disclosure.

FIG. 9 is a schematic diagram of a memory device, in accordance with various embodiments of the present disclosure.

FIG. 10 is a schematic diagram of a memory device, in accordance with various embodiments of the present disclosure.

FIG. 11 illustrates waveforms of signals in the memory device in FIG. 10, in accordance with some embodiments of the present disclosure.

FIG. 12 is a schematic diagram of a memory device, in accordance with various embodiments of the present disclosure.

FIG. 13 is a flow chart of a method of operating a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

As used herein, the terms “comprising,” “including,” “having,” “containing,” “involving,” and the like are to be understood to be open-ended, i.e., to mean including but not limited to.

As used herein, “around”, “about”, “approximately” or “substantially” shall generally refer to any approximate value of a given value or range, in which it is varied depending on various arts in which it pertains, and the scope of which should be accorded with the broadest interpretation understood by the person skilled in the art to which it pertains, so as to encompass all such modifications and similar structures. In some embodiments, it shall generally mean within 20 percent, preferably within 10 percent, and more preferably within 5 percent of a given value or range. Numerical quantities given herein are approximate, meaning that the term “around”, “about”, “approximately” or “substantially” can be inferred if not expressly stated, or meaning other approximate values.

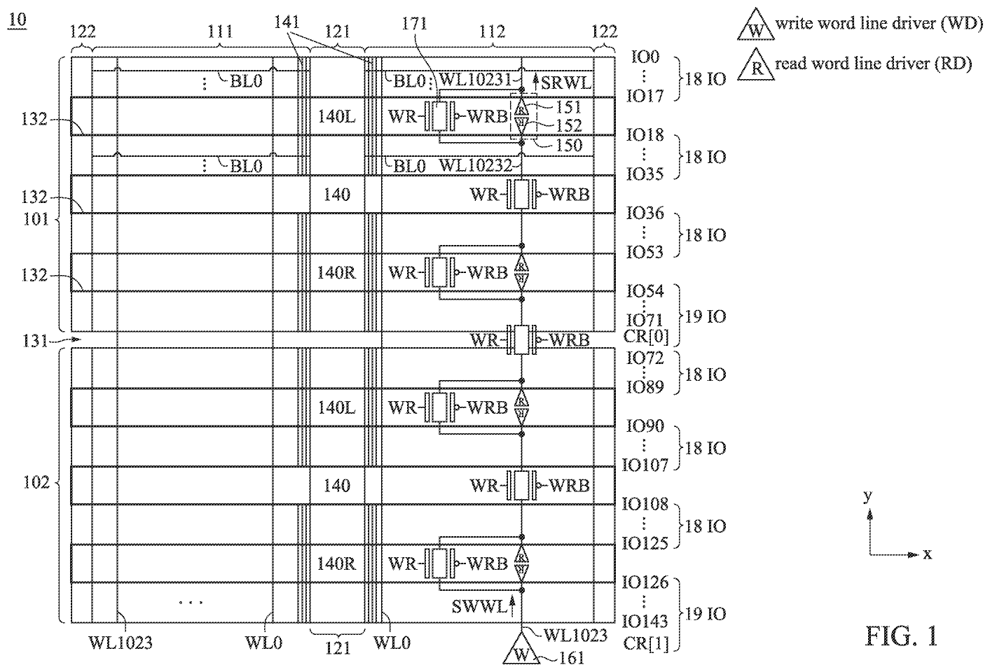

Reference is now made to FIG. 1. FIG. 1 is a schematic diagram of a memory device 10, in accordance with various embodiments of the present disclosure. For illustration, the memory device 10 includes memory banks 101 and 102 that are arranged and separated from each other along y direction by a control region 131. Each of the memory banks 101 and 102 includes memory arrays 111 and 112 that are separated from each other by control regions 132. As shown in FIG. 1, two adjacent memory arrays 111 and 112 are separated by an input/output circuitry 121. In some embodiments, each of the input/output circuitries 121 includes numbers of input/output circuits, for example, IO0 to IO17, in which each of the input/output circuits is coupled to a corresponding group (e.g., 32 bit lines) of bit lines BL0 to BL575 for receiving/outputting data from/to memory array (e.g., memory arrays 111 or 112) in memory operations, for example, a read operation and write operation. In some embodiments, the input/output circuitry 121 includes two sets of the input/output circuits IO0 to IO17 for the memory array 111 and 112 respectively. As illustratively shown in FIG. 1, the input/output circuitry 121 on the edge of the memory bank 101 and adjacent the control region 131 includes 19 input/output circuits, for example, IO54 to IO71 and CR [0], the input/output circuit CR [0] is configured as a redundant circuit to replace one—being malfunctioning—in the input/output circuits IO0 to IO71.

In the embodiments of FIG. 1, the memory bank 101 further includes edge input/output circuits 122 that are arranged along edges of the memory bank 101 in y direction and configured to cooperate with the input/output circuitry 121 for transmitting signals during the memory operations.

The memory bank 101 includes control circuits 140, 140L and 140R, read drivers 150 in the control regions 132. In some embodiments, the control circuit 140 is interposed between the control circuits 140L and 140R, and coupled to the control circuits 140L and 140R through conductive lines 141 for transmitting control signals in memory operations. In some embodiments, the read driver 150 includes read word line drivers 151 to 152 that are coupled to two adjacent memory arrays 112 respectively. In some embodiments, the read word line drivers 151 and 152 are referred to as local word line drivers. The configurations of the memory bank 102 are similar to those of the memory bank 101. Hence, the repetitious descriptions are omitted here.

In some embodiments, the memory device 10 further includes two sets of word lines WL0 to WL1023. For the sake of simplicity, only word line WL1023 is given in FIG. 1 for illustrative purposes. The memory device 10 further includes write word line drivers 161 at an edge of the memory bank 102 and each of the write word line drivers 161 is coupled to a corresponding one in the word lines WL0 to WL1023. The write word line drivers 161 are referred to as global word line drivers. In some embodiments, a first set of word lines WL0 to WL1023 are coupled to 1024 rows of memory cells in the memory arrays 111 in the memory banks 101 and 102, and a second set of word lines WL0 to WL1023 are coupled to 1024 rows of memory cells in the memory arrays 112 in the memory banks 101 and 102. The word lines WL0 to WL1023 extend in y direction and pass the memory banks 101 and 102 to couple the read drivers 150 to the write word line drivers 161. In the embodiments of FIG. 1, each one of the write word line drivers 161 are coupled to around 4608 memory cells arranged in a row, in which 32 memory cells are coupled to the single input/output circuit in the input/output circuitry 121.

For example, as shown in FIG. 1, the word line WL1023 is coupled to the read word line drivers 151 and the read word line drivers 152 that are arranged in a row (for example, along y direction) through pass gates 171. In some embodiments, each of the pass gates 171 is coupled between two adjacent read drivers 150. The read drivers 150 and the pass gates 171 are arranged in the control regions 132, and one pass gate 171 is arranged in the control region 131 between two memory banks 101 and 102.

As illustratively shown in the embodiments of FIG. 1, each of the pass gates 171 is coupled between output terminals of two adjacent read word line drivers 151 and 152. For illustration, a terminal of the pass gate 171 is coupled to a portion (e.g., a portion WL10231 coupled to one of the memory array 112) of the word line WL1023 at an output terminal of the read word line driver 151. The other terminal of the pass gate 171 is coupled to another portion (e.g., a portion WL10232 coupled to another of the memory array 112) of the word line WL1023 at an output terminal of the read word line driver 152, and further coupled to one terminal of another pass gate 171.

In some embodiments, the pass gate 171 includes one P-type transistor (e.g., a P-type metal oxide semiconductor) and an N-type transistor (e.g., a P-type metal oxide semiconductor). Drain terminals of the P-type and N-type transistors are coupled together. Source terminals of the P-type and N-type transistors are coupled together. A gate terminal of the N-type transistor receives a control signal WR and a gate terminal of the P-type transistor receives a control signal WRB that has an inverted state of that of the control signal WR. In some embodiments, the control signals WR and WRB are generated by the control circuits 140, 140L, and 140R.

According to some embodiments, in a write operation performed to a selected memory cell that is in the memory banks 101 to 102 and coupled to the word line WL1023 depicted in FIG. 1, the control signal WR has a high logic state to turn on the N-type transistor in the pass gate 171 and the control signal WRB has a low logic state to turn on the P-type transistor in the pass gate 171. All of the pass gate 171 are turned on (e.g., conducted) in response to the control signals WR and WRB to transmit a write word line signal SWWL on the word line WL1023.

In a read operation performed to a selected memory cell that is in the memory banks 101 to 102 and coupled to the word line WL1023 depicted in FIG. 1, the control signal WR has a low logic state to turn off the N-type transistor in the pass gate 171 and the control signal WRB has a high logic state to turn off the P-type transistor in the pass gate 171. Accordingly, all of the pass gate 171 are turned off (e.g., dis-conducted) in response to the control signals WR and WRB to electrically disconnect the memory arrays in the memory banks 101 and 102 from the write word line driver 161. The output terminals of the read word line drivers 151 and 152 are electrically isolated from each other correspondingly. In some embodiments, each of the read word line drivers 151 and 152 is configured to generate a read word line signal SRWL to a corresponding portion of the word line WL1023 coupled thereto. For example, the read word line driver 151 generates the read word line signal SRWL to the portion WL10231, as illustratively shown in FIG. 1.

In operation, accordingly to some embodiments, the control circuit 140 is configured to access memory cells in the memory arrays 111 and 112 of the memory bank 101 in the read operation and in the write operation by controlling the control circuits 140L and 140R. The control circuits 140L and 140R further control the input/output circuitries 121, the edge input/output circuits 122, the read drivers 150, and the write word line drivers 161 to perform the read operation and in the write operation. Further configurations of operating the memory device 10 will be discussed in the following paragraphs with reference to FIGS. 1 to 4.

The configurations of FIG. 1 are given for illustrative purposes. Various implements are within the contemplated scope of the present disclosure. For example, in some embodiments, the memory device 10 excludes the edge input/output circuits 122. In various embodiments, the memory bank 101 excludes the redundant input/output circuit CR [0], and the memory bank 102 excludes the redundant input/output circuit CR [1].

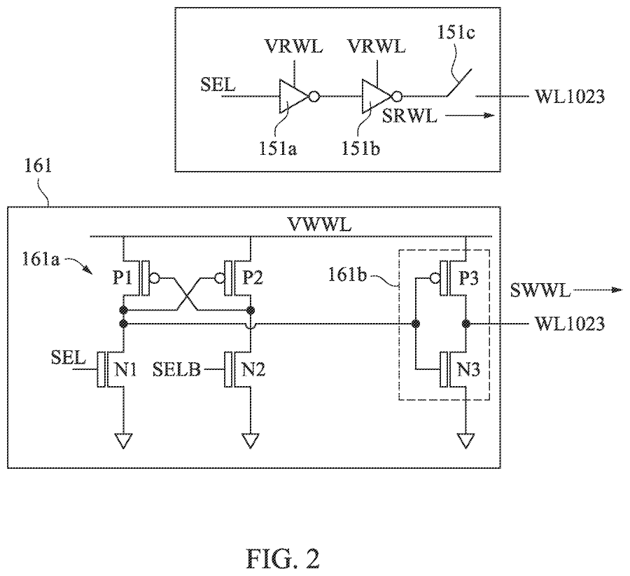

Reference is now made to FIG. 2. FIG. 2 illustrates schematic diagrams of the read word line driver 151 or 152 and the write word line driver 161 that correspond to FIG. 1, in accordance with other embodiments of the present disclosure.

For illustration, the read word line driver 151 includes an inverter 151a coupled to an inverter 151b in series. In some embodiments, the inverters 151a and 151b operate in response to a voltage VRWL. Specifically, the inverter 151a receives the select signal SEL at an input terminal thereof and generates responsive to the select signal SEL an inverted signal to an input terminal of the inverter 151b. The inverter 151b receives the inverted signal at an input terminal thereof and generates responsive to the inverted signal the read word line signal SRWL at an output terminal of the inverter 151b.

The read word line driver 151 further includes a switch 151c operating in response to a switching signal from the control circuit, for example, 140, 140R, or 140L of FIG. 1. In some embodiments of the read operation performed to the selected memory cell coupled to the word line WL1023, the select SEL has a high logic state and the switch 151c is turned on to conduct the inverter 151b to the word line WL1023. Accordingly, the read word line driver 151 generates the read word line signal SRWL having the voltage VRWL to the word line WL1023.

The configurations of the read word line driver 152 are similar to those of the read word line driver 151. Hence, the repetitious descriptions are omitted here.

For illustration, the write word line driver 161 includes a level shifter 161a and an inverter 161b. The level shifter 161a includes transistors N1, N2, P1, and P2, and the inverter 161b includes transistors N3 and P3. In some embodiments, the transistors N1, N2, and N3 are NMOS transistors, and the transistors P1, P2, and P3 are PMOS transistors. In some embodiments, a gate terminal of the transistor N1 is electrically connected to the output terminal of the word line decoder circuit (not shown) to receive a select signal SEL. A drain terminal of the transistor N1 is electrically connected to a node no1, and a source terminal of the transistor N1 is electrically connected to the low voltage supply terminal (e.g., ground). When gate-source voltage VGS of the transistor N1 is greater than threshold voltage VTH of the transistor N1, the transistor N1 turns on to pull down voltage at the node no1. When the gate-source voltage VGS of the transistor N1 is less than the threshold voltage VTH of the transistor N1, the transistor N1 turns off to present high impedance looking into the drain terminal of the transistor N1 from the node no1.

In some embodiments, the level shifter 161a further includes an inverter that is configured to generate a select signal SELB inverted from the select signal SEL and further to transmit it to the transistor N2.

The transistor N2 is a pull-down transistor for pulling down the voltage at the node no2. A gate terminal of the transistor N2 is configured receive the select signal SELB. A drain terminal of the transistor N2 is electrically connected to the node no2, and a source terminal of the transistor N2 is electrically connected to the low voltage supply terminal (e.g., ground). When gate-source voltage VGS of the transistor N2 is greater than threshold voltage VTH of the transistor N2, the transistor N2 turns on to pull down voltage at the node no2. When the gate-source voltage VGS of the transistor N2 is less than the threshold voltage VTH of the transistor N2, the transistor N2 turns off to present high impedance looking into the drain terminal of the transistor N2 from the node no2.

A gate terminal of the transistor P1 is electrically connected to the node no2. A drain terminal of the transistor P1 is electrically connected to the node no1, and a source terminal of the transistor P1 is electrically connected to a voltage supply terminal providing voltage VWWL. When source-gate voltage VSG of the transistor P1 is greater than threshold voltage VTH of the transistor P1, the transistor P1 turns on to pull up voltage at the node no1 to about the voltage VWWL, which is a high voltage in write operations. When the source-gate voltage VSG of the transistor P1 is less than the threshold voltage VTH of the transistor P1, the transistor P1 turns off to present high impedance looking into the drain terminal of the transistor P1 from the node no1.

A gate terminal of the transistor P2 is electrically connected to the gate terminals of the transistors N3 and P3 at the node no1, which is also an inverting output of the level shifter 161a. A drain terminal of the transistor P2 is electrically connected to the node no2, and a source terminal of the transistor P2 is electrically connected to the voltage supply providing the voltage VWWL. When source-gate voltage VSG of the transistor P2 is greater than threshold voltage VTH of the transistor P2, the transistor P2 turns on to pull up voltage at the node no2 to about the voltage VWWL. When the source-gate voltage VSG of the transistor P2 is less than the threshold voltage VTH of the transistor P2, the transistor P2 turns off to present high impedance looking into the drain terminal of the transistor P2 from the node no2.

In some embodiments of a write operation performed to the selected memory cell that is coupled to a certain word line, for example WL1023, in the memory device 10, the word line decoder receives an address signal associated with the selected memory cell and generates the select signal SEL having a high logic state (e.g., a logic high value “1”). The transistor N1 is turned on, and the transistor N1 pulls down voltage at the gate terminal of the transistor P2 (node no1) to a low voltage (e.g., ground). The low voltage at the gate terminal of the transistor P2 turns on the transistor P2 (VSG>VTH), so that the voltage at the node no2 is pulled up to about the voltage VWWL. The gate terminal of the transistor N2 receives the select signal SELB having a low logic state (e.g., a logic low value “0”). The logic low voltage turns off the transistor N2.

Accordingly, with the voltage at the node no1 low, the transistor P3 turns on to pull up the voltage at the node nout to the voltage VWWL to generate the write word line signal SWWL having the voltage VWWL to the word line, for example, WL1023.

When the selected memory cell is not coupled to the word line WL1023, the select signal SEL transmitted from the word line decoder to the write word line driver 161 coupled to the word line WL1023 has the low logic state.

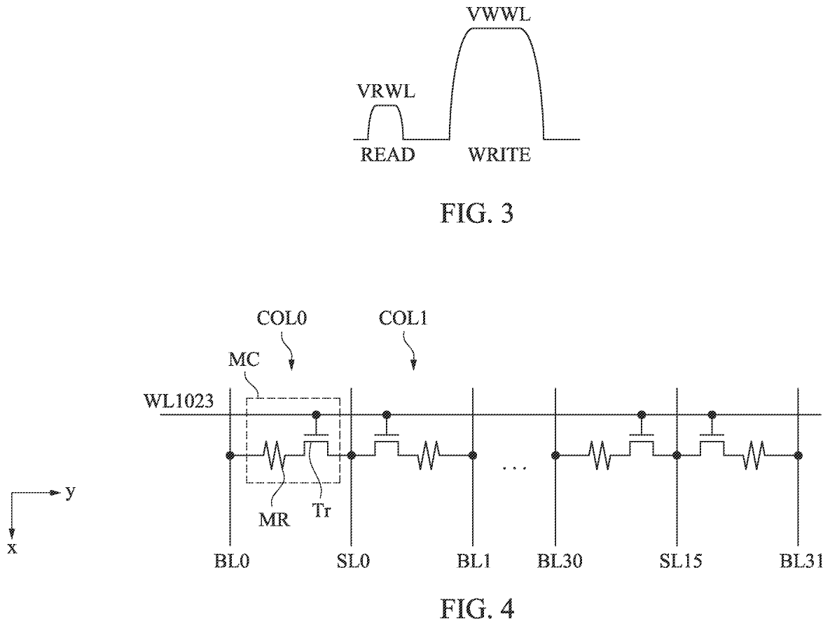

In some embodiments, as shown in FIG. 3 illustrating waveforms of the read word line signal SRWL and the write word line signal SWWL corresponding to FIGS. 1-2, in accordance with some embodiments of the present disclosure.

The voltage VRWL is different from the voltage VWWL. For illustration, the voltage VRWL is smaller than the voltage VWWL. In some embodiments, performing the read operation requires a small voltage, for example, around 1 Volt, and a high operation speed, for example, a rising time of around 5 nano seconds in the pulse of the read word line signal SRWL, in order to obtain a stable cell current and to reduce read access time. On contrary, performing the write operation requires a higher voltage, for example, around 2 to 3 Volts, in the pulse of the write word line signal SWWL, in order to turn on selector in the memory cell for set operation and reset operation.

The configurations of FIGS. 2-3 are given for illustrative purposes. Various implements are within the contemplated scope of the present disclosure. For example, in some embodiments, the write word line driver 161 includes other suitable forms of the level shifter different from the embodiments of FIG. 2.

Reference is now made to FIG. 4. FIG. 4 is a schematic diagram of part of the memory array 111 or 112 corresponding to FIG. 1, in accordance with some embodiments of the present disclosure.

In some embodiments, the memory array 111 includes memory cells MC arranged in columns and rows of the memory array 111. The memory cells MC include resistive random access memory (RRAM) cells. As shown in FIG. 4, the memory cells within a row (along y direction) of the memory array 111 are coupled to a corresponding one of word lines, for example, WL1023. The memory cells within a column (along x direction) are (operably) coupled to a corresponding bit line. For example, the memory cell MC in the column COL0 is coupled to the bit line BL0. In the embodiments of FIG. 4, the memory cells MC in adjacent columns (e.g., in the columns COL0-COL1) are coupled to a same select line, for example, SL0. The memory cells MC are respectively associated with an address defined by an intersection of a corresponding word line and a corresponding bit line.

The memory cell MC includes an RRAM device MR and an access transistor Tr. The RRAM device MR has a resistive state that is switchable between a low resistive state and a high resistive state. The resistive states are indicative of a data value (e.g., a “1” or “0”) stored within the RRAM device MR. The RRAM device MR has a terminal coupled to a bit line, for example, BL0 and the other terminal coupled to the access transistor Tr. The access transistor Tr has a gate terminal coupled to a word line, for example, WL1023, a source terminal coupled to a select line, for example, SL0, and a drain terminal coupled to the second terminal of the RRAM device MR.

In operation, with reference to FIGS. 1-4, by activating the word line WL1023 through the write word line driver 161 transmitting the word line signal SWWL having the voltage VWWL, the access transistor Tr is turned on, allowing for a select line SL0 to be coupled to the second terminal of the RRAM device MR.

The memory arrays 111 are coupled to support circuitry including the input/output circuitry 121, the edge input/output circuit 122, the control circuits 140L, 140R, in which the support circuitry is configured to read data from and/or write data to the memory cells. In some embodiments, the support circuitry further includes a word line decoder circuit, a bit line decoder, a select line decoder, and a sensing circuitry (not shown). In some embodiments, the control circuits 140, 140L, and 140R include the word line decoder circuit, the bit line decoder, the select line decoder, a sensing circuitry, or the combination thereof.

In some embodiments, the word line decoder circuit is configured to generate the select signals SEL to the write word line driver 161 to selectively apply the voltage VWWL to a selected word line based upon an address ADD corresponding to the selected memory cell MC for access operation. The bit line decoder is configured to selectively apply a signal to one of the bit lines based upon the address ADD. The select line decoder is configured to selectively apply a signal to one of the select lines based upon the address ADDR.

By selectively applying signals to the word lines, the bit lines, and the select lines, the support circuitry is able to perform forming, reset, write and read operations on selected ones of the memory cells MC. For example, during an read operation to read data from memory cell MC coupled to the word line WL1023, the bit line BL0, and the select line SL0, the read word line driver 151 or read word line driver 152 applies the voltage VRWL to the word line WL1023, the bit line decoder applies a signal (e.g., voltage) to bit line BL0, and the select line decoder applies a signal (e.g., voltage) to the select line SL0. The applied signals cause the sensing circuitry to receive a signal (e.g., voltage) having a value that is dependent upon a data state of the memory cell MC. The sensing circuitry is configured to sense this signal and to determine the data state of the selected memory cell MC based on the signal (e.g., by comparing a received voltage to a reference voltage).

In other embodiments of a write operation of writing data into the memory cells MC coupled to the word line WL1023, the bit line BL0, and the select line SL0, the write word line driver 161 applies the voltage VWWL to the word line WL1023, the bit line decoder applies a signal (e.g., voltage) to bit line BL0, and the select line decoder applies a signal (e.g., voltage) to the select line SL0. Accordingly, the state of the RRAM device MR changes according to the data being written.

In some approaches, a pair of a read word line driver and a write word line driver is configured to generate word line signals in read and write operations to a certain memory array. The write word line drivers demand high reliability so as not to suffer stress concerns, and occupy large area due to the numerous elements of level shifters in the word line drivers, however, issuing area overhead in memory design.

With the configurations of the present application, as shown in FIG. 1, by employing a global write word line driver for multiple memory arrays and a read word line drivers for individual memory array, the total area of word line drivers in input/output circuitry significantly shrinks, addressing area overhead impact induced by write word line drivers.

Moreover, compared with some approaches adopting the scheme of driving great number of columns of memory cells through a long word line coupled thereto, the memory device 10 in the present application utilizes local read word line drivers to drive less memory cells through shorter word line, greatly reducing the resistive effect and the capacitive effect that are induced by resistor-capacitor (RC) loading of the word line. Accordingly, it accelerates the transmission speed of signals in the word line. For example, the rising time of the pulse in the read word line signal SRWL reduces by around 50 percent and the falling time of the pulse in the read word line signal SRWL reduces by around 40 percent, which provides a high speed read sensing structure.

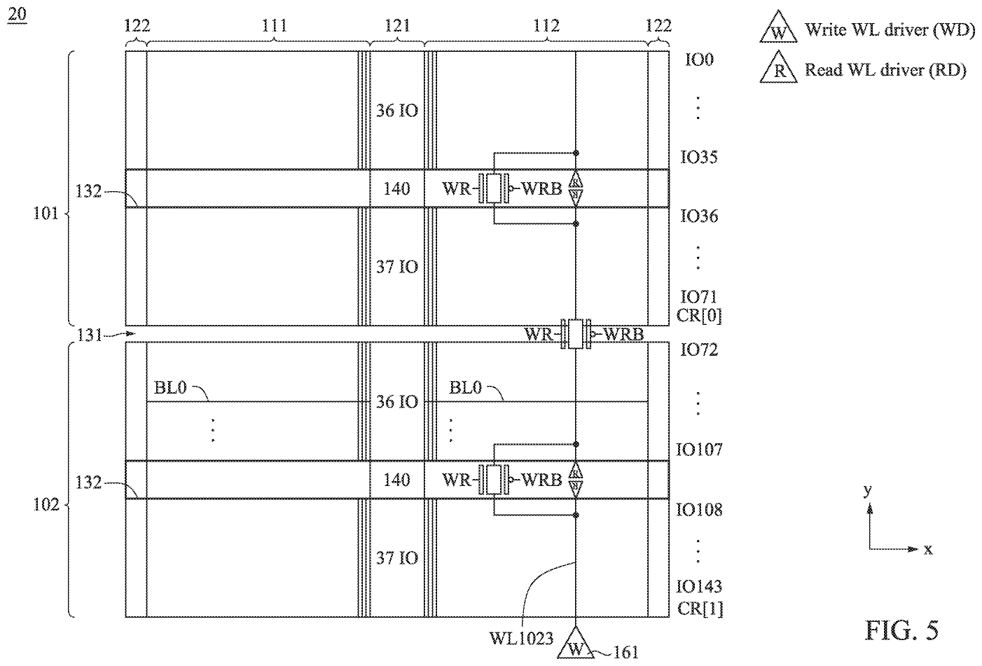

Reference is now made to FIG. 5. FIG. 5 is a schematic diagram of a memory device 20, in accordance with various embodiments of the present disclosure. With respect to the embodiments of FIGS. 1-4, like elements in FIG. 5 are designated with the same reference numbers for ease of understanding. In some embodiments, the memory device 20 is configured with respect to, for example, the memory device 10 of FIG. 1.

Compared with the embodiments of FIG. 1, each of the memory banks 101-102 includes one control region 132 that separates two adjacent memory arrays along y direction. In some embodiments, each of the input/output circuitries 121 in FIG. 5 includes 36 input/output circuits, for example, IO0 to IO35, in which each of the input/output circuits is coupled to a corresponding group (e.g., 32 bit lines) of bit lines BL0 to BL1151 for receiving/outputting data from/to memory array (e.g., memory arrays 111 or 112) in memory operations, for example, the read operation and write operation controlled by the control circuit 140. Some input/output circuitries 121 includes redundant input/output circuit CR [0] or CR [1].

With the configurations of the present application, the write word line driver 161 is coupled to two pairs of the read word line drivers 151-152 in the memory banks 101-102, which saves around 6% of memory macro area, compared with some approaches. Furthermore, the memory banks 101-102 have similar configurations, providing simplicity in complier design while only the memory bank, for example, 102, at the edge is configured to be coupled to the write word line driver 161.

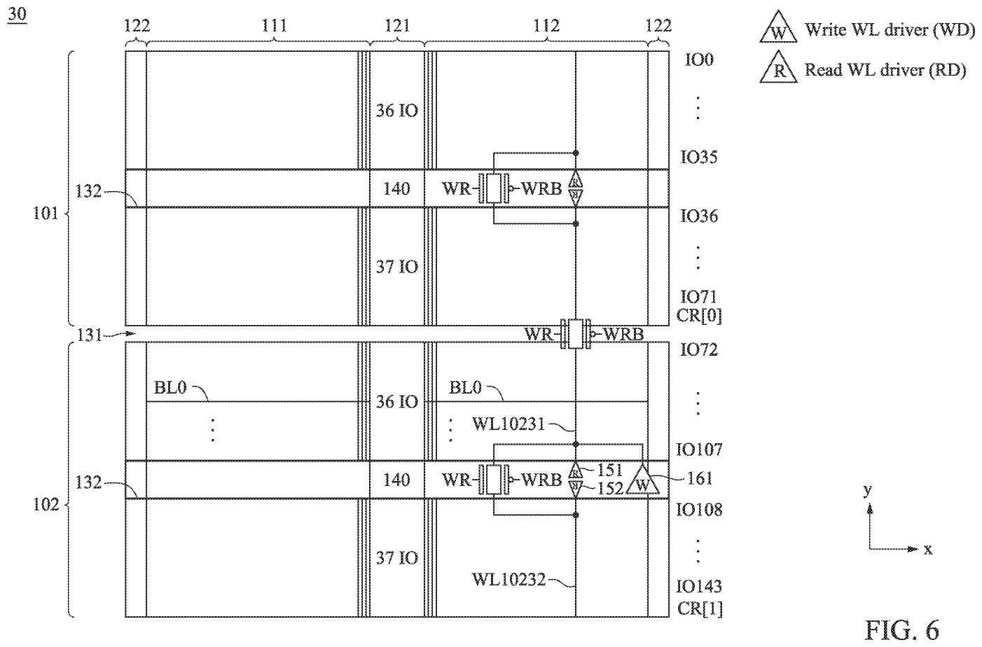

Reference is now made to FIG. 6. FIG. 6 is a schematic diagram of a memory device 20, in accordance with various embodiments of the present disclosure. With respect to the embodiments of FIGS. 1-5, like elements in FIG. 6 are designated with the same reference numbers for ease of understanding. In some embodiments, the memory device 30 is configured with respect to, for example, the memory device 20 of FIG. 5.

Compared with the embodiments of FIG. 5, the write word line driver 161 is arranged in the control region 132 and coupled to the word line WL1023. In some embodiments, the read word line drivers 151-152 and the write word line driver 161 in the same control region 132 share metal tracks, and accordingly, routing resources are economically saved.

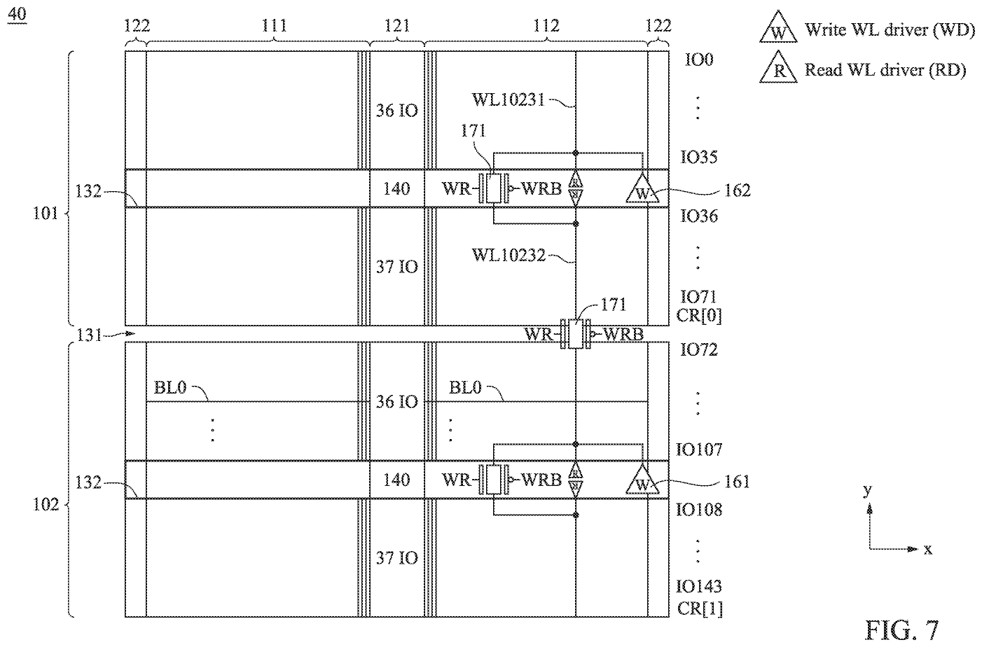

Reference is now made to FIG. 7. FIG. 7 is a schematic diagram of a memory device 40, in accordance with various embodiments of the present disclosure. With respect to the embodiments of FIGS. 1-6, like elements in FIG. 7 are designated with the same reference numbers for ease of understanding. In some embodiments, the memory device 40 is configured with respect to, for example, the memory device 30 of FIG. 6.

Compared with the embodiments of FIG. 6, the memory device 40 further includes a write word line driver 162 configured with respect to, for example, the write word line driver 161. For illustration, the write word line driver 162 is arranged in the control region 132 of the memory bank 101 and coupled to portions of the word line WL1023 to drive the memory cells in the memory bank 101. Accordingly, the driving loading during the write operation for the memory banks 101-102 are balanced. In some embodiments, the read word line drivers 151-152 and the write word line driver 162 in the same control region 132 share metal tracks, and accordingly, routing resources are economically saved.

The configurations of FIG. 7 are given for illustrative purposes. Various implements are within the contemplated scope of the present disclosure. For example, in some embodiments, the pass gate 171 in the control region 131 is eliminated.

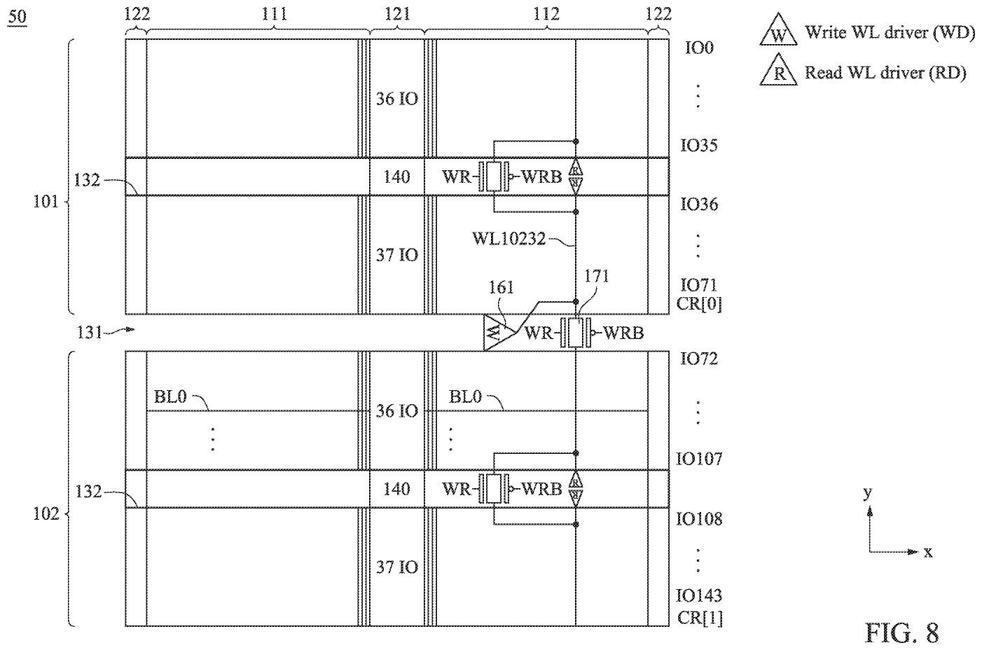

Reference is now made to FIG. 8. FIG. 8 is a schematic diagram of a memory device 50, in accordance with various embodiments of the present disclosure. With respect to the embodiments of FIGS. 1-7, like elements in FIG. 8 are designated with the same reference numbers for ease of understanding. In some embodiments, the memory device 50 is configured with respect to, for example, the memory device 20 of FIG. 5.

Compared with the embodiments of FIG. 5, instead of arranging the write word line driver 161 at one edge of one memory bank, the write word line driver 161 in the FIG. 8 in the control region 131 between the memory banks 101-102. Alternatively stated, the write word line driver 161 is interposed between two edges of the two memory banks to drive memory cells MC in the memory banks 101-102, balancing the driving loading during the write operation for the memory banks 101-102.

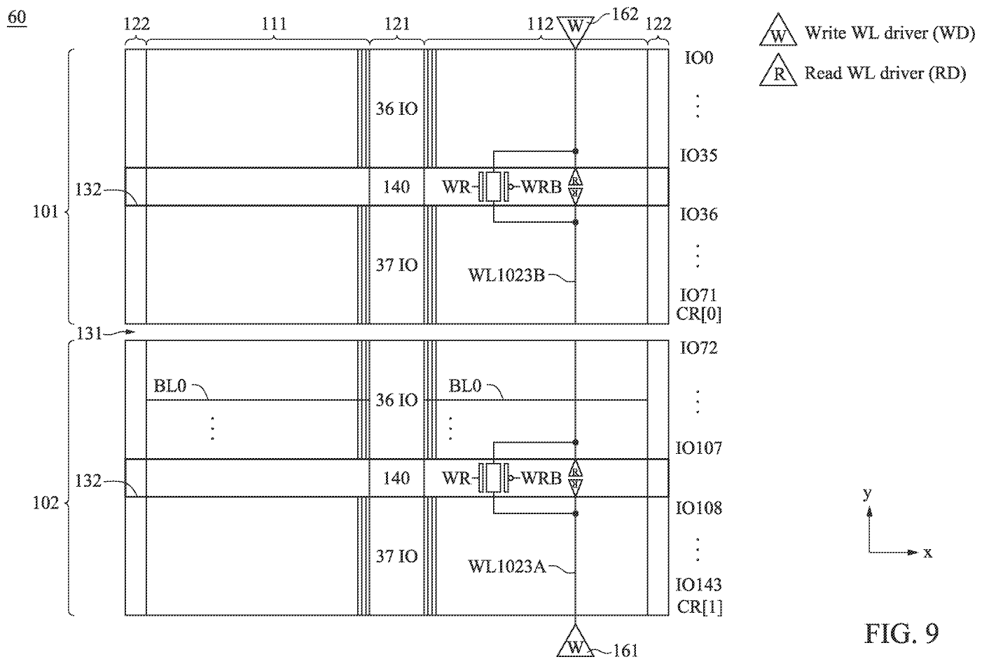

Reference is now made to FIG. 9. FIG. 9 is a schematic diagram of a memory device 60, in accordance with various embodiments of the present disclosure. With respect to the embodiments of FIGS. 1-8, like elements in FIG. 9 are designated with the same reference numbers for ease of understanding. In some embodiments, the memory device 60 is configured with respect to, for example, the memory device 40 of FIG. 7.

Compared with the embodiments of FIG. 7, instead of arranging the write word line drivers 161-162 in the control regions 132, the write word line driver 161 in the FIG. 9 is arranged at an edge of the memory bank 101, and the write word line driver 162 is arranged at an edge of the memory bank 102. The write word line driver 161 is coupled to the read word line drivers 151-152 and the memory cells MC in the memory bank 102 through a word line WL1023A. Similarly, the write word line driver 162 is coupled to the read word line drivers 151-152 and the memory cells MC in the memory bank 101 through a word line WL1023B. The word line WL1023A-WL1023B are configured with respect to, for example, the word line WL1023 of FIG. 1. In some embodiments, the word line WL1023A-WL1023B are separated by the control region 131.

With the configurations of FIG. 9, the rising speed of the pulses in the write word line signals SWWL generated by the two write word line drivers 161-162 accelerates. Furthermore, the IR drop in the word lines WL1023A-WL1023B improves due to shorter length of the word lines coupled to the memory cells MC.

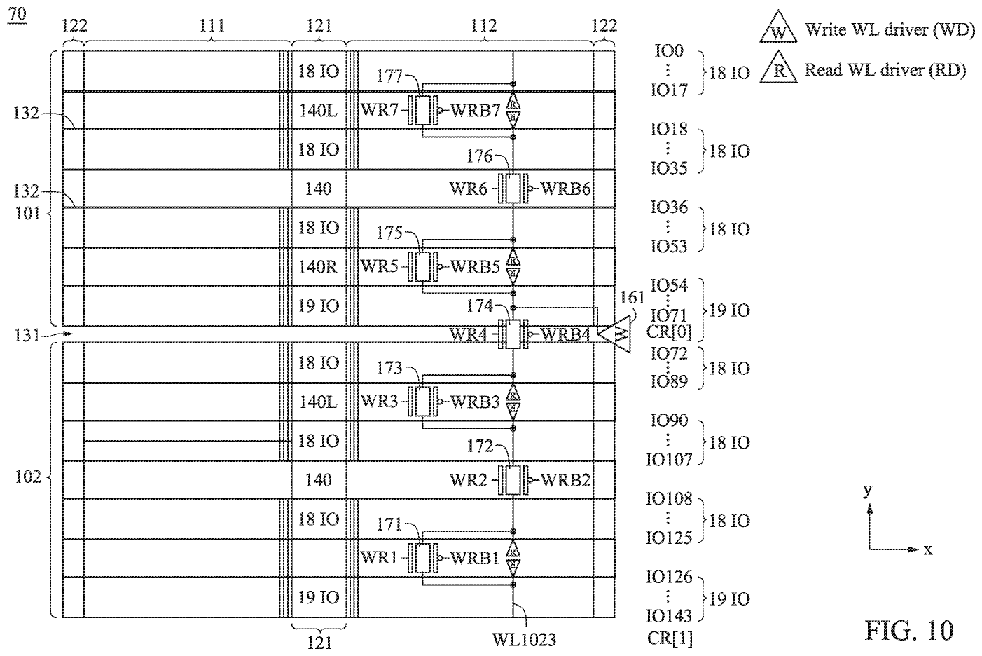

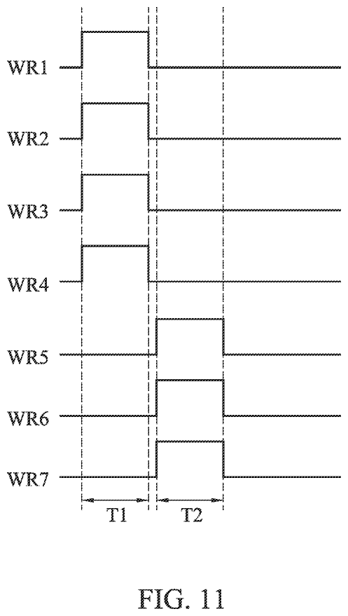

Reference is now made to FIGS. 10-11. FIG. 10 is a schematic diagram of a memory device 70, and FIG. 11 illustrates waveforms of control signals WR1-WR7 and WRB1-WRB7 in the memory device 70 in FIG. 10, in accordance with various embodiments of the present disclosure. With respect to the embodiments of FIGS. 1-9, like elements in FIGS. 10-11 are designated with the same reference numbers for ease of understanding. In some embodiments, the memory device 70 is configured with respect to, for example, the memory device 10 of FIG. 1.

Compared with the embodiments of FIG. 1, the pass gates coupled to the word line WL1023 receive different control signals in order to transmit the write word line signal SWWL from the write word line driver 161 to different memory arrays. For example, the memory device 70 includes pass gates 172-177 configured with respect to, for example, the pass gate 171. The pass gates 171-177 receive the control signals WR1-WR7 and WRB1-WRB7 separately as shown in FIG. 10. The pass gates 171-173 are arranged in the control region 132 in the memory bank 102, the pass gates 175-177 are arranged in the control region 132 in the memory bank 101, and the pass gate 174 is interposed between the memory banks 101 and 102. Instead of arranging the write word line driver 161 at the edge of the memory bank 102, the write word line driver 161 is arranged between the memory banks 101-102 in the memory device 70, and coupled between the pass gates 174-175.

In some embodiments, with reference to FIGS. 10-11 together, in a time interval T1, the control signals WR1-WR4 have the high logic state (the control signals WRB1-WRB4 have the low logic state), and the control signal WR5-WR7 have the low logic state (the control signals WRB5-WRB7 have the high logic state). The pass gates 171-174 of FIG. 10 are turned on in response to the control signals WR1-WR4 and WRB1-WRB4 to transmit the voltage VWWL from the write word line driver 161 to the memory cells MC coupled to the input/output circuits IO72-IO143 for turning on the access transistors in the memory cells MC. The pass gates 175-177 are turned off in response to the control signals WR5-WR7 and WRB5-WRB7, which reduces loading and leakage of the word line.

The configurations of FIGS. 10-11 are given for illustrative purposes. Various implements are within the contemplated scope of the present disclosure. For example, in some embodiments, the control signals WR1-WR7 and WRB1-WRB7 have different logic states in response to the write operation performed to the selected memory cell MC in the memory banks 101-102.

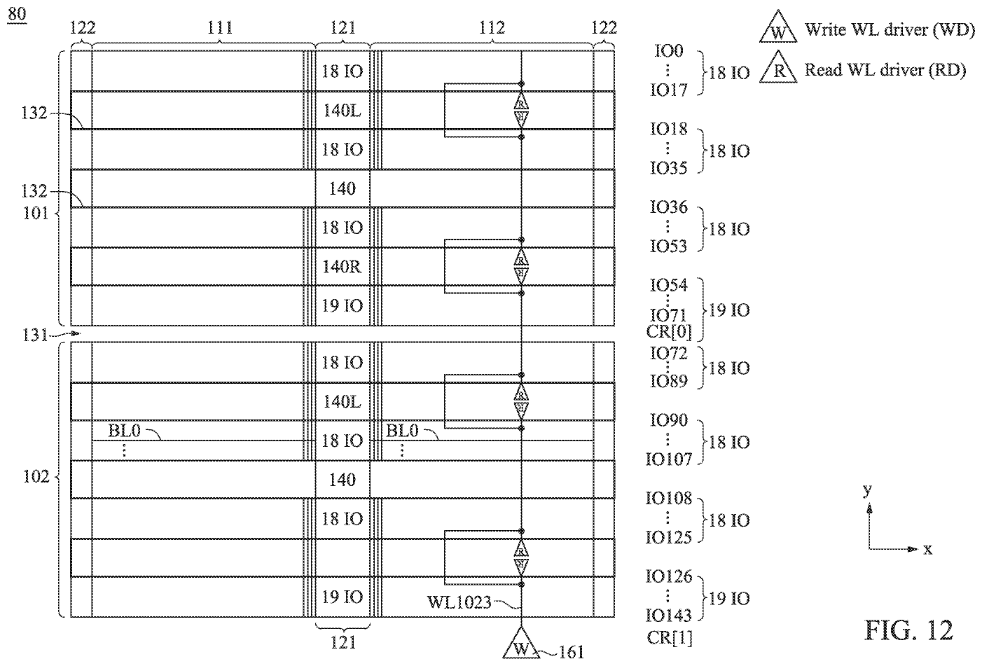

Reference is now made to FIG. 12. FIG. 12 is a schematic diagram of a memory device 80, in accordance with various embodiments of the present disclosure. With respect to the embodiments of FIGS. 1-11, like elements in FIG. 12 are designated with the same reference numbers for ease of understanding. In some embodiments, the memory device 80 is configured with respect to, for example, the memory device 10.

Compared with the embodiments of FIG. 1, the memory device 80 does not include pass gates 171 coupled to the word line WL1023. Accordingly, reduced area is provided by the memory device 80 and high operational speed is achieved by utilizing simply metal routing between memory arrays.

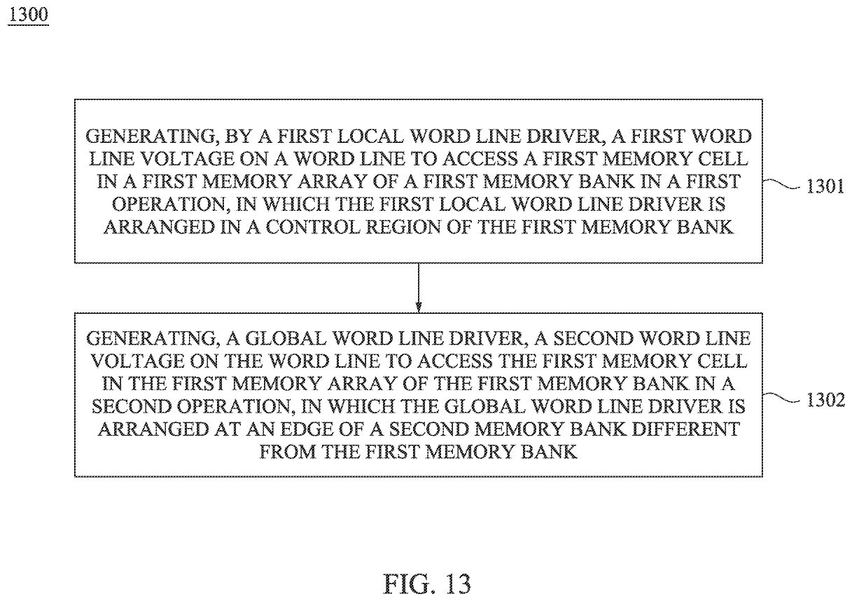

Reference is now made to FIG. 13. FIG. 13 is a flow chart of a method 1300 of operating the memory device 10, 20, 30, 40, 50, 60, 70, or 80 in FIGS. 1-12, in accordance with some embodiments. It is understood that additional operations/stages can be provided before, during, and after the processes shown by FIG. 13, and some of the operations/stages described below can be replaced or eliminated, for additional embodiments of the method 1300. The method 1300 includes operations 1301-1302 and will be discussed in the following paragraphs with reference to FIGS. 1A-12.

In operation 1301, as shown in FIG. 1, the read word line driver 151 generates the voltage VRWL on the word line, for example, WL1023 to access a memory cell in the memory array 112 of the memory bank 101 in a read operation. In some embodiments, the aforementioned memory cell is coupled to the portion WL10231.

In some embodiments, the method 1300 further includes operations of performing another read operation to another memory cell in another memory array of the memory bank 101. For example, the read word line driver 152 generates the voltage VRWL on the word line WL1023 to access a memory cell that is coupled to the portion WL10232.

With continued reference to FIG. 1, the method 1300 further includes operations of performing yet another read operation to yet another memory cell in a memory array of the memory bank 102 separated from the memory bank 101. For example, the read word line driver 151 generates the voltage VRWL on the word line WL1023 to access a memory cell of the memory array 112 in the memory bank 102.

In operation 1302, as shown in FIG. 1, the write word line driver 161 generates the voltage VWWL on the word line WL1023 to access the memory cell in the memory array 112 of the memory bank 101 in a write operation.

In some embodiments, the method 1300 further includes operations of transmitting, by the pass gates 171 in the control regions 131 and 132, the voltage VWWL in response to control signals WR and WRB. As shown in FIG. 1, the pass gates 171 are turned on to transmit the voltage VWWL to the word line WL1023 to access memory cells coupled thereto in the write operation.

In some embodiments, the method 1300 further includes operations of alternately switching the pass gates in different memory operations. For example, as shown in FIG. 10, the pass gates 171-174 of FIG. 10 are turned on to transmit the voltage VWWL from the write word line driver 161 to the memory bank 101 in the write operation performed to a memory cell in the memory bank 101 while the pass gates 175-177 are turned off to electrically disconnect the memory bank 102 from the write word line driver 161.

As described above, a memory device is provided and includes a global write word line driver used for multiple memory arrays, while individual memory arrays employ read word line drivers. This configuration significantly reduces the overall area occupied by word line drivers in the input/output circuitry, effectively mitigating the area overhead caused by write word line drivers. Furthermore, the configurations of the memory device significantly minimize the resistive and capacitive effects caused by the resistor-capacitor (RC) loading of the word line, resulting in faster signal transmission within the word line. This leads to a notable improvement in signal speed, reducing the rising time and the falling time of the read word line signal, establishing a high-speed read sensing structure.

In some embodiments, a memory device is disclosed. The memory device includes multiple first memory arrays, a first write word line driver, and multiple first read word line drivers. Each of the first read word line drivers is coupled to one array in the first memory arrays. A selected one in the first read word line drivers generates a first word line voltage to a corresponding array in the first memory arrays in a first read operation. A first write word line driver is coupled to at least two drivers in the first read word line drivers, and generates a second word line voltage to the first memory arrays in a first write operation. The second word line voltage is greater than the first word line voltage.

In some embodiments, the first read word line drivers are arranged in multiple first control regions of multiple memory banks. The first write word line driver is arranged an edge of one in the memory banks.

In some embodiments, the first write word line driver is arranged between two of the memory banks.

In some embodiments, the memory device further includes multiple second read word line drivers each coupled to one array in multiple second memory arrays. A selected one in the second read word line drivers is configured to generate the first word line voltage to a corresponding array in the second memory arrays in a second read operation. The memory device further includes a second write word line driver coupled to at least two drivers in the second read word line drivers, and configured to generate the second word line voltage to the second memory arrays in a second write operation. The first read word line drivers are arranged in a first memory bank, and the second read word line drivers are arranged in a second memory bank. The first write word line driver is arranged at an edge of the first memory bank, and the second write word line driver is arranged at an edge of the second memory bank.

In some embodiments, the memory device further includes a pass gate coupled between output terminals of the at least two drivers in the first read word line drivers, and configured to electrically connect a first portion of a word line with a second portion of the word line in the first write operation. The first portion of the word line is coupled to a first driver in the at least two drivers, and the second portion of the word line is coupled to a second driver in the at least two drivers. The first write word line driver is coupled to the first memory arrays through the word line.

In some embodiments, the pass gate, the at least two drivers, and the first write word line driver are arranged in a control region in a memory bank.

In some embodiments, the first read word line drivers are arranged in a first memory bank. The memory device further includes multiple second read word line drivers each coupled to one array in multiple second memory arrays in a second memory bank. A selected one in the second read word line drivers is configured to generate the first word line voltage to a corresponding array in the second memory arrays in a second read operation. The memory device further includes a pass gate coupled between one in the first read word line drivers and one in the second read word line drivers. The first write word line driver is further configured to generate the second word line voltage to the second memory arrays in a second write operation.

In some embodiments, the first write word line driver and the pass gate are arranged between the first memory bank and the second memory bank.

In some embodiments, the memory device further includes multiple pass gates each coupled between two adjacent first read word line drivers and configured to be turned on to electrically transmit the second word line voltage to the first memory arrays.

In some embodiments, the memory device further includes multiple pass gates each coupled between two adjacent first read word line drivers in the first read word line drivers. A first group of the pass gates are configured to be turned on in response to multiple control signals to transmit the second word line voltage to some of the first memory arrays when a second group of the pass gates are turned off.

Also disclosed is a memory device that includes a first word line extending in a first direction; multiple first read word line drivers arranged in multiple first control regions that extend in a second direction and are interposed between multiple first memory arrays; and a first write word line driver coupled to the first word line. A selected one in the first read word line drivers is configured to generate a first word line voltage to activate the first word line in a read operation. The first write word line driver is configured to generate a second word line voltage to activate the first word line in a write operation. The first word line voltage and the second word line voltage are different from each other.

In some embodiments, the first control regions are included in multiple memory banks. The first word line crosses the memory banks.

In some embodiments, the first write word line driver is arranged at an edge of one in the memory banks.

In some embodiments, the first word line includes multiple portions each coupled to one in the first read word line drivers. The memory device further includes multiple pass gates configured to electrically couple the portions of the first word line with each other in response to multiple control signals.

In some embodiments, the memory device further includes a second word line extending in the first direction and separated from the first word line in the second direction; multiple second read word line drivers arranged in multiple second control regions that extend in the second direction and are interposed between multiple second memory arrays. A selected one in the second read word line drivers is configured to generate the first word line voltage to activate the second word line. The memory device further includes a second write word line driver coupled to the second word line and configured to generate the second word line voltage to activate the second word line. The first read word line drivers are arranged in a first memory bank and the second read word line drivers are arranged in a second memory bank adjacent to the first memory bank. The first write word line driver and the second write word line driver are arranged on opposite sides of the first and second memory banks.

Also disclosed is a method of operating a memory device includes following operations: generating, by a first local word line driver, a first word line voltage on a word line to access a first memory cell in a first memory array of a first memory bank in a first operation, wherein the first local word line driver is arranged in a control region of the first memory bank; and generating, a global word line driver, a second word line voltage on the word line to access the first memory cell in the first memory array of the first memory bank in a second operation, wherein the global word line driver is arranged at an edge of a second memory bank different from the first memory bank.

In some embodiments, the method further includes operations of generating, by a second local word line driver, the first word line voltage on the word line to access a second memory cell in a second memory array of the first memory bank in a third operation. The second local word line driver is arranged in the control region of the first memory bank and coupled to the global word line driver through the word line. The first word line voltage is smaller than the second word line voltage.

In some embodiments, the method further includes operations of generating, by a third local word line driver, the first word line voltage on the word line to access a third memory cell in a first memory array of the second memory bank in a fourth operation. The third local word line driver is arranged in a control region of the second memory bank and coupled to the global word line driver through the word line.

In some embodiments, the method further includes operations of transmitting, by first and second pass gates, the second word line voltage to the word line in response to a plurality of control signals. The first pass gate is arranged in the control region of the first memory bank and coupled between output terminals of the first local word line driver and the second local word line driver. The second pass gate is arranged between the first memory bank and the second memory bank and coupled between the second local word line driver and the third local word line driver.

In some embodiments, the method further includes operations of turning on a plurality of first pass gates to transmit the second word line voltage from the global word line driver to the first memory bank in the second operation while turning off a plurality of second pass gates to electrically disconnect a second memory bank from the global word line driver.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a plurality of first memory arrays;
a plurality of first read word line drivers each coupled to one array in the plurality of first memory arrays, wherein a selected one in the plurality of first read word line drivers is configured to generate a first word line voltage to a corresponding array in the plurality of first memory arrays in a first read operation; and
a first write word line driver coupled to at least two drivers in the plurality of first read word line drivers, and configured to generate a second word line voltage to the plurality of first memory arrays in a first write operation, wherein the second word line voltage is greater than the first word line voltage.

2. The memory device of claim 1, wherein the plurality of first read word line drivers are arranged in a plurality of first control regions of a plurality of memory banks, and
the first write word line driver is arranged an edge of one in the plurality of memory banks.

3. The memory device of claim 2, wherein the first write word line driver is arranged between two of the plurality of memory banks.

4. The memory device of claim 1, further comprising:
a plurality of second read word line drivers each coupled to one array in a plurality of second memory arrays, wherein a selected one in the plurality of second read word line drivers is configured to generate the first word line voltage to a corresponding array in the plurality of second memory arrays in a second read operation; and
a second write word line driver coupled to at least two drivers in the plurality of second read word line drivers, and configured to generate the second word line voltage to the plurality of second memory arrays in a second write operation,
wherein the plurality of first read word line drivers are arranged in a first memory bank, and the plurality of second read word line drivers are arranged in a second memory bank,
wherein the first write word line driver is arranged at an edge of the first memory bank, and the second write word line driver is arranged at an edge of the second memory bank.

5. The memory device of claim 1, further comprising:
a pass gate coupled between output terminals of the at least two drivers in the plurality of first read word line drivers, and configured to electrically connect a first portion of a word line with a second portion of the word line in the first write operation,
wherein the first portion of the word line is coupled to a first driver in the at least two drivers, and the second portion of the word line is coupled to a second driver in the at least two drivers,
wherein the first write word line driver is coupled to the plurality of first memory arrays through the word line.

6. The memory device of claim 5, wherein the pass gate, the at least two drivers, and the first write word line driver are arranged in a control region in a memory bank.

7. The memory device of claim 1, wherein the plurality of first read word line drivers are arranged in a first memory bank,
wherein the memory device further comprises:
a plurality of second read word line drivers each coupled to one array in a plurality of second memory arrays in a second memory bank, wherein a selected one in the plurality of second read word line drivers is configured to generate the first word line voltage to a corresponding array in the plurality of second memory arrays in a second read operation; and
a pass gate coupled between one in the plurality of first read word line drivers and one in the plurality of second read word line drivers;
wherein the first write word line driver is further configured to generate the second word line voltage to the plurality of second memory arrays in a second write operation.

8. The memory device of claim 7, wherein the first write word line driver and the pass gate are arranged between the first memory bank and the second memory bank.

9. The memory device of claim 1, further comprising:
a plurality of pass gates each coupled between two adjacent first read word line drivers and configured to be turned on to electrically transmit the second word line voltage to the plurality of first memory arrays.

10. The memory device of claim 1, further comprising:
a plurality of pass gates each coupled between two adjacent first read word line drivers in the plurality of first read word line drivers,
wherein a first group of the plurality of pass gates are configured to be turned on in response to a plurality of control signals to transmit the second word line voltage to some of the plurality of first memory arrays when a second group of the plurality of pass gates are turned off.

11. A memory device, comprising:
a first word line extending in a first direction;
a plurality of first read word line drivers arranged in a plurality of first control regions that extend in a second direction and are interposed between a plurality of first memory arrays, wherein a selected one in the plurality of first read word line drivers is configured to generate a first word line voltage to activate the first word line in a read operation; and
a first write word line driver coupled to the first word line and configured to generate a second word line voltage to activate the first word line in a write operation, wherein the first word line voltage and the second word line voltage are different from each other.

12. The memory device of claim 11, wherein the plurality of the first control regions are included in a plurality of memory banks,
wherein the first word line crosses the plurality of memory banks.

13. The memory device of claim 12, wherein the first write word line driver is arranged at an edge of one in the plurality of memory banks.

14. The memory device of claim 11, wherein the first word line comprises a plurality of portions each coupled to one in the plurality of first read word line drivers,
wherein the memory device further comprises:
a plurality of pass gates configured to electrically couple the plurality of portions of the first word line with each other in response to a plurality of control signals.

15. The memory device of claim 11, further comprising:
a second word line extending in the first direction and separated from the first word line in the second direction;
a plurality of second read word line drivers arranged in a plurality of second control regions that extend in the second direction and are interposed between a plurality of second memory arrays, wherein a selected one in the plurality of second read word line drivers is configured to generate the first word line voltage to activate the second word line; and
a second write word line driver coupled to the second word line and configured to generate the second word line voltage to activate the second word line,
wherein the plurality of first read word line drivers are arranged in a first memory bank and the plurality of second read word line drivers are arranged in a second memory bank adjacent to the first memory bank,
wherein the first write word line driver and the second write word line driver are arranged on opposite sides of the first and second memory banks.

16. A method, comprising:
generating, by a first local word line driver, a first word line voltage on a word line to access a first memory cell in a first memory array of a first memory bank in a first operation, wherein the first local word line driver is arranged in a control region of the first memory bank; and
generating, a global word line driver, a second word line voltage on the word line to access the first memory cell in the first memory array of the first memory bank in a second operation, wherein the global word line driver is arranged at an edge of a second memory bank different from the first memory bank.

17. The method of claim 16, further comprising:
generating, by a second local word line driver, the first word line voltage on the word line to access a second memory cell in a second memory array of the first memory bank in a third operation, wherein the second local word line driver is arranged in the control region of the first memory bank and coupled to the global word line driver through the word line,
wherein the first word line voltage is smaller than the second word line voltage.

18. The method of claim 17, further comprising:
generating, by a third local word line driver, the first word line voltage on the word line to access a third memory cell in a first memory array of the second memory bank in a fourth operation, wherein the third local word line driver is arranged in a control region of the second memory bank and coupled to the global word line driver through the word line.

19. The method of claim 18, further comprising:
transmitting, by first and second pass gates, the second word line voltage to the word line in response to a plurality of control signals,
wherein the first pass gate is arranged in the control region of the first memory bank and coupled between output terminals of the first local word line driver and the second local word line driver,
wherein the second pass gate is arranged between the first memory bank and the second memory bank and coupled between the second local word line driver and the third local word line driver.

20. The method of claim 16, further comprising:
turning on a plurality of first pass gates to transmit the second word line voltage from the global word line driver to the first memory bank in the second operation while turning off a plurality of second pass gates to electrically disconnect a second memory bank from the global word line driver.
